(19) United States
(12) Patent Application Publication
(10) Pub. No.: US 2024/0298445 A1
(43) Pub. Date: Sep. 5, 2024

(54) SEMICONDUCTOR MEMORY DEVICE AND MANUFACTURING METHOD THEREOF

(71) Applicant: Kioxia Corporation, Tokyo (JP)

(72) Inventors: Yosuke MITSUNO, Yokkaichi Mie (JP); Ryouji MASUDA, Yokkaichi Mie (JP); Tatsufumi HAMADA, Nagoya Aichi (JP); Tomohiro KUKI, Yokkaichi Mie (JP); Yusuke MORIKAWA, Yokkaichi Mie (JP)

(73) Assignee: Kioxia Corporation, Tokyo (JP)

(21) Appl. No.: 18/587,080

(22) Filed: Feb. 26, 2024

(30) Foreign Application Priority Data
Mar. 1, 2023 (JP) 2023-031298
Nov. 24, 2023 (JP) 2023-199384

(51) Int. Cl. H10B 43/27

(52) U.S. Cl. CPC H10B 43/27

(57) ABSTRACT

A semiconductor memory device has a chip shape. A stacked body is formed by alternately stacking, in a first direction, a plurality of first insulating layers and a plurality of first conductive layers each of which functions as a control gate of a memory cell transistor. A first columnar body extends in the first direction in the stacked body and includes a first semiconductor portion. An insulating film is provided at an end portion of the semiconductor memory device. A second columnar body extends in the first direction in the insulating film and includes a second semiconductor portion that is shorter than the first semiconductor portion in the first direction. An impurity concentration of the second semiconductor portion at a bottom portion of the second columnar body is higher than that of the first semiconductor portion at an intersection portion between the first columnar body and the first conductive layer.

### CROSS-REFERENCE TO RELATED APPLICATION (S)

This application is based upon and claims the benefit of priority from Japanese Patent Application No. 2023-031298, filed Mar. 1, 2023 and Japanese Patent Application No. 2023-199384, filed Nov. 24, 2023, the entire contents of which are incorporated herein by reference.

### FIELD

Embodiments described herein relate generally to a semiconductor memory device and a manufacturing method thereof.

### BACKGROUND

A semiconductor memory device such as a NAND flash memory may include a three-dimensional memory cell array in which memory cells are located in a three-dimensional manner. In order to increase a cell current of the three-dimensional memory cell array, it is required to improve carrier mobility in a channel portion of the memory cell.

### DESCRIPTION OF THE DRAWINGS

FIG. 1 is a cross-sectional view illustrating a configuration example of a semiconductor memory device according to a first embodiment.

FIG. 2 is a plan view illustrating a configuration example of a stacked body.

FIG. 3 is a cross-sectional view illustrating a memory cell having a three-dimensional structure.

FIG. 4 is a cross-sectional view illustrating the memory cell having the three-dimensional structure.

FIG. 5 is a schematic plan view illustrating a configuration example of an array chip of the semiconductor memory device according to the first embodiment.

FIG. 6 is a cross-sectional view illustrating a configuration example of a dummy columnar portion.

FIG. 7 is a cross-sectional view illustrating a configuration example of one dummy columnar portion.

FIG. 8 is a cross-sectional view illustrating a semiconductor body of a columnar portion and the dummy columnar portion according to the first embodiment and a periphery thereof.

FIG. 9 is a cross-sectional view illustrating an example of a manufacturing method of the semiconductor memory device according to the first embodiment.

FIG. 10A is a cross-sectional view illustrating the example of the manufacturing method of the semiconductor memory device, following FIG. 9.

FIG. 10B is a cross-sectional view illustrating the example of the manufacturing method of the semiconductor memory device, following FIG. 9.

FIG. 11A is a cross-sectional view illustrating the example of the manufacturing method of the semiconductor memory device, following FIG. 10A.

FIG. 11B is a cross-sectional view illustrating an example of the manufacturing method of the semiconductor memory device, following FIG. 10B.

FIG. 12 is a cross-sectional view illustrating the example of the manufacturing method of the semiconductor memory device, following FIG. 11A.

FIG. 13A is a cross-sectional view illustrating the example of the manufacturing method of the semiconductor memory device, following FIG. 12.

FIG. 13B is a cross-sectional view illustrating an example of the manufacturing method of the semiconductor memory device, following FIG. 11B.

FIG. 14 is a cross-sectional view of a portion of a broken line frame B in FIG. 13A.

FIG. 15 is a cross-sectional view illustrating the example of the manufacturing method of the semiconductor memory device, following FIG. 14.

FIG. 16 is a cross-sectional view illustrating the example of the manufacturing method of the semiconductor memory device, following FIG. 15.

FIG. 17A is a cross-sectional view illustrating the example of the manufacturing method of the semiconductor memory device, following FIG. 16.

FIG. 17B is a cross-sectional view illustrating the example of the manufacturing method of the semiconductor memory device, following FIG. 13B.

FIG. 18 is a cross-sectional view illustrating an example of a manufacturing method of a semiconductor memory device according to a first modification of the first embodiment.

FIG. 19 is a cross-sectional view illustrating the example of the manufacturing method of the semiconductor memory device, following FIG. 18.

FIG. 20 is a cross-sectional view illustrating a configuration example of a semiconductor memory device according to a second modification of the first embodiment.

FIG. 21 is a cross-sectional view illustrating the configuration example of the semiconductor memory device according to the second modification of the first embodiment.

FIG. 22 is a cross-sectional view illustrating an example of a manufacturing method of a semiconductor memory device according to a second embodiment.

FIG. 23 is a cross-sectional view illustrating the example of the manufacturing method of the semiconductor memory device, following FIG. 22.

FIG. 24 is a conceptual diagram illustrating hydrogenation treatment.

FIG. 25 is a conceptual diagram illustrating the hydrogenation treatment.

FIG. 26 is a graph illustrating a relationship between a hydrogenation temperature and a concentration of a mobile electron.

### DETAILED DESCRIPTION

Embodiments provide a semiconductor memory device including a memory cell array having improved carrier mobility of a channel portion and a manufacturing method thereof.

In general, according to at least one embodiment, a semiconductor memory device has a chip shape. A stacked body is formed by alternately stacking, in a first direction, a plurality of first insulating layers and a plurality of first conductive layers each of which functions as a control gate of a memory cell transistor. A first columnar body extends in the first direction in the stacked body and includes a first semiconductor portion. An insulating film is provided at an end portion of the semiconductor memory device. A second columnar body extends in the first direction in the insulating film and includes a second semiconductor portion that is shorter than the first semiconductor portion in the first direction. An impurity concentration of the second semiconductor portion at a bottom portion of the second columnar body is higher than an impurity concentration of the first semiconductor portion at an intersection portion between the first columnar body and the first conductive layer.

Hereinafter, embodiments according to the present disclosure will be described with reference to the drawings. The embodiments do not limit the present disclosure. The drawings may be schematically or conceptually illustrated. In the specification and drawings, the same elements will be denoted by the same reference numerals.

### First Embodiment

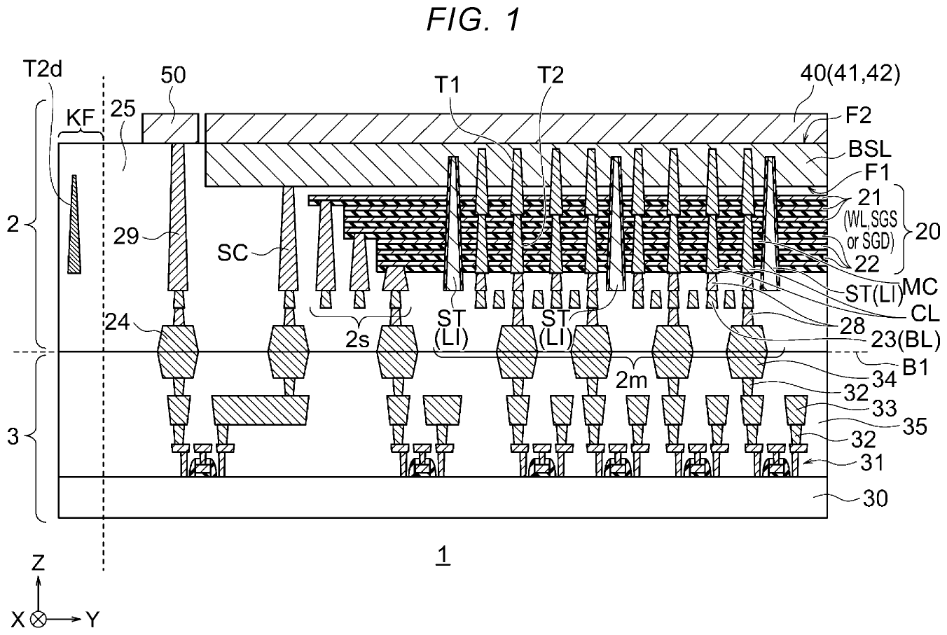

FIG. 1 is a cross-sectional view illustrating a configuration example of a semiconductor memory device 1 according to a first embodiment. Hereinafter, a stacking direction of a stacked body 20 will be referred to as a Z direction. A direction that intersects, for example, is orthogonal to the Z direction is defined as a Y direction. A direction that intersects, for example, is orthogonal to each of the Z direction and the Y direction is defined as an X direction. It is noted that in this specification, the X direction is an example of a third direction, the Y direction is an example of a second direction, and the Z direction is an example of a first direction.

The semiconductor memory device 1 includes an array chip 2 having a memory cell array and a CMOS chip 3 having a CMOS circuit. The array chip 2 and the CMOS chip 3 are bonded to each other on a bonding surface B1 and are electrically connected to each other via a wiring bonded on the bonding surface B1. FIG. 1 illustrates a state in which the array chip 2 is mounted on the CMOS chip 3. The semiconductor memory device 1 is obtained by allowing the array chip 2 in a wafer state and the CMOS chip 3 in a wafer state to be bonded to each other and dicing the bonded one into a chip shape.

The CMOS chip 3 includes a substrate 30, a transistor 31, a via 32, wirings 33 and 34, and an interlayer insulating film 35.

The substrate 30 is, for example, a semiconductor substrate such as a silicon substrate. The transistor 31 is an NMOS or PMOS transistor provided on the substrate 30. The transistor 31 forms, for example, the CMOS circuit that controls the memory cell array of the array chip 2. The transistor 31 is an example of a plurality of logical circuits. Semiconductor elements such as a resistance element and a capacitive element other than the transistor 31 may be formed on the substrate 30.

The via 32 electrically connects the transistor 31 to the wiring 33 or electrically connects the wiring 33 to the wiring 34. The wirings 33 and 34 form a multilayer wiring structure within the interlayer insulating film 35. The wiring 34 is buried in the interlayer insulating film 35 and is exposed substantially flush with a surface of the interlayer insulating film 35. The wirings 33 and 34 are electrically connected to the transistor 31 and the like. For example, a low resistance metal such as copper or tungsten is used for the via 32 and the wirings 33 and 34. The interlayer insulating film 35 covers and protects the transistor 31, the via 32, and the wirings 33 and 34. For example, an insulating film such as a silicon oxide film is used for the interlayer insulating film 35.

The array chip 2 includes the stacked body 20, a columnar body CL, a slit ST (LI), a semiconductor source layer BSL, a metal layer 40, a contact 29, and a bonding pad 50.

The stacked body 20 is provided above the transistor 31 and is located in the Z direction with respect to the substrate 30. The stacked body 20 is formed by alternately stacking a plurality of electrode films 21 and a plurality of insulating films 22 in the Z direction. The stacked body 20 and the columnar body CL form the memory cell array. For example, a conductive metal such as tungsten is used for the electrode film 21. For example, an insulating film such as a silicon oxide film is used for the insulating film 22. The insulating film 22 insulates the electrode films 21 from each other. That is, the plurality of electrode films 21 are stacked in a mutually insulated state. The number of layers of each of the electrode films 21 and the insulating films 22 is freely selected. The insulating film 22 may be, for example, a porous insulating film or an air gap.

One or the plurality of electrode films 21 at an upper end and a lower end of the stacked body 20 in the Z direction function as a source-side select gate SGS and a drain-side select gate SGD, respectively. The electrode film 21 between the source-side select gate SGS and the drain-side select gate SGD functions as a word line WL. The word line WL is a gate electrode (a control gate) of a memory cell MC. The drain-side select gate SGD is a gate electrode of a drain-side select transistor. The source-side select gate SGS is provided in a lower area of the stacked body 20. The drain-side select gate SGD is provided in an upper area of the stacked body 20. The upper area refers to an area of the stacked body 20 on the side closer to the CMOS chip 3, and the lower area refers to an area of the stacked body 20 on the side far from the CMOS chip 3 (the side close to the metal layer 40).

The semiconductor memory device 1 has a plurality of memory cells (memory cell transistors) MC connected in series between a source-side select transistor and the drain-side select transistor. A structure in which the source-side select transistor, the memory cell MC, and the drain-side select transistor are connected in series is referred to as a “memory string” or a “NAND string”. The memory string is connected to, for example, a bit line BL via a via 28. The bit line BL is a wiring 23 that is provided below the stacked body 20 and extends in the X direction (direction of the paper surface in FIG. 1).

A plurality of the columnar bodies CL are provided in the stacked body 20. The columnar body CL extends in the stacked body 20 so as to penetrate the stacked body 20 in a stacking direction (in the Z direction) of the stacked body 20, and is provided from the via 28 connected to the bit line BL to the semiconductor source layer BSL. The internal structure of the columnar body CL will be described later. In the present embodiment, since the columnar body CL has a high aspect ratio, the columnar body CL is divided into two stages (columnar portions T1 and T2) in the Z direction. The columnar portion T2 is formed after the columnar portion T1. The columnar body CL may be formed of one stage or three or more stages.

Additionally, a plurality of the slits ST (LI) are provided in the stacked body 20. The slit ST (LI) extends in the X direction and penetrates the stacked 20 in the stacking direction (in the Z direction) of the stacked body 20. The slit ST (LI) is filled with an insulating film such as a silicon oxide film, and the insulating film has a plate shape. The slit ST (LI) electrically isolates the electrode films 21 of the stacked body 20. Alternatively, an inner wall of the slit ST (LI) may be coated with an insulating film such as a silicon oxide film, and further, a conductive material may be buried inside the insulating film. In this case, the conductive material also functions as a source wiring LI that reaches the semiconductor source layer BSL. That is, the slit ST may be the source wiring LI electrically that is isolated from the electrode film 21 of the stacked body 20 forming the memory cell array and is electrically connected to the semiconductor source layer BSL. The slit is also referred to as ST (LI).

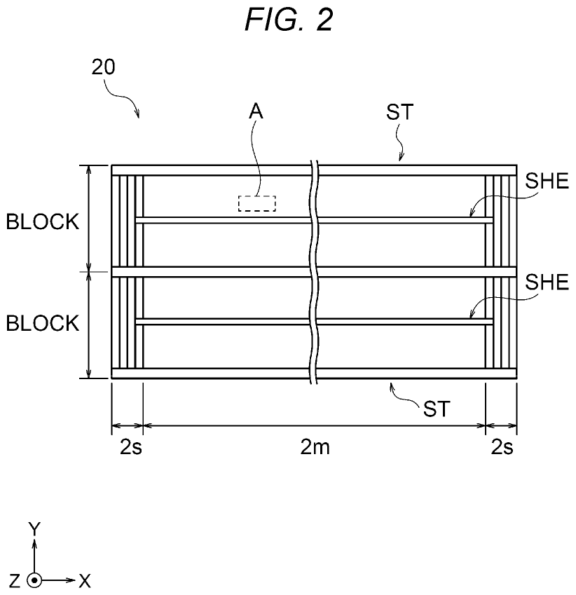

The semiconductor source layer BSL is provided on the stacked body 20. The semiconductor source layer BSL is an example of a first semiconductor layer. The semiconductor source layer BSL is provided corresponding to the stacked body 20. The semiconductor source layer BSL has a first surface F1 and a second surface F2 on the side opposite to the first surface F1. The stacked body 20 (the memory cell array) is provided on the first surface F1 side of the semiconductor source layer BSL, and the metal layer 40 is provided on the second surface F2 side. The metal layer 40 includes a source line 41 and a power line 42. The source line 41 and the power supply line 42 will be described in detail later. The semiconductor source layer BSL is commonly connected to one end of the plurality of columnar bodies CL, and applies a common source voltage to the plurality of columnar bodies CL located in the same memory cell array 2m. That is, the semiconductor source layer BSL functions as a common source electrode of the memory cell array 2m. For example, a conductive material such as doped polysilicon is used for the semiconductor source layer BSL. For example, a metal material having a lower resistance than that of the semiconductor source layer BSL, such as copper, aluminum, or tungsten, is used for the metal layer 40. It is noted that 2s is a stepped portion of the electrode film 21 provided to connect the contact 29 to each electrode film 21. The stepped portion 2s will be described later with reference to FIG. 2.

Meanwhile, the bonding pad 50 is provided on the stacked body 20 in an area in which the semiconductor source layer BSL is not provided. The bonding pad 50 is an example of a first electrode. The bonding pad 50 is connected to a metal wire or the like (not illustrated) and receives power supply from the outside of the semiconductor memory device 1. The bonding pad 50 is connected to the transistor 31 of the CMOS chip 3 via the contact 29, a wiring 24, and the wiring 34. Therefore, the external power supplied from the bonding pad 50 is supplied to the transistor 31. For example, a low resistance metal such as copper or tungsten is used for the contact 29.

In the present embodiment, the array chip 2 and the CMOS chip 3 are formed separately and are bonded to each other on the bonding surface B1. Therefore, no transistor 31 is provided in the array chip 2. Further, the stacked body 20 (the memory cell array) is not provided in the CMOS chip 3. Both the transistor 31 and the stacked body 20 are located on the first surface F1 side of the semiconductor source layer BSL. The transistor 31 is located on the side opposite to the second surface F2 on which metal layer 40 is located.

The via 28, the wiring 23, and the wiring 24 are provided below the stacked body 20. The wirings 23 and 24 are buried in an interlayer insulating film 25 and are exposed substantially flush with a surface of the interlayer insulating film 25. The wirings 23 and 24 are electrically connected to a semiconductor body 210 and the like of the columnar body CL. For example, a low resistance metal such as copper or tungsten is used for the via 28, the wiring 23, and the wiring 24. The interlayer insulating film 25 covers and protects the stacked body 20, the via 28, the wiring 23, and the wiring 24. For example, an insulating film such as a silicon oxide film is used for the interlayer insulating film 25.

A dummy columnar portion T2d is provided in the interlayer insulating film 25 of a kerf area KF so as to extend in the Z direction. The dummy columnar portion T2d is formed in the same process as the columnar portion T2 and has the same configuration as that of the columnar body CL. However, the dummy columnar portion T2d is provided at an outer edge portion (end portion) KF of the array chip 2 of the semiconductor memory device 1. The outer edge portion KF is a remaining portion of a dicing area that is cut when a semiconductor wafer is cut and fragmented into the array chips 2 in a dicing process. The outer edge portion KF can also be referred to as, for example, an area outside a guard ring or an edge seal, or an area not covered with polyimide (passivation). A dummy pattern that does not function as a memory, such as an alignment mark in a photolithography process and a test pattern, may be formed in the outer edge portion KF. The dummy columnar portion T2d is a part of the dummy pattern formed in the outer edge portion KF and is not used as the memory cell.

The interlayer insulating film 25 and the interlayer insulating film 35 are bonded to each other on the bonding surface B1, and both the wiring 24 and the wiring 34 are bonded to each other substantially flush with the bonding surface B1. Accordingly, the array chip 2 and the CMOS chip 3 are electrically connected to each other via the wiring 24 and the wiring 34.

FIG. 2 is a plan view illustrating a configuration example of the stacked body 20. The stacked body 20 includes the stepped portion 2s and the memory cell array 2m. The stepped portion 2s is provided at an edge portion of the stacked body 20. The memory cell array 2m is interposed between or surrounded by the stepped portions 2s. The slit ST (LI) is provided from the stepped portion 2s at one end of the stacked body 20, through the memory cell array 2m, to the stepped portion 2s at the other end of the stacked body 20. A slit SHE is provided at least in the memory cell array 2m. The slit SHE is shallower than the slit ST (LI) and extends substantially parallel to the slit ST (LI). The slit SHE electrically isolates the electrode film 21 for each drain-side select gate SGD.

A portion of the stacked body 20 interposed between the two slits ST (LI) illustrated in FIG. 2 is referred to as a block (BLOCK). The block forms, for example, a minimum unit of data erasure. The slit SHE is provided in the block. The stacked body 20 disposed between the slit ST (LI) and the slit SHE is referred to as a finger. The drain-side select gate SGD is divided for each finger. Therefore, when writing and reading data, one finger in the block can be put into a selected state by the drain-side select gate SGD.

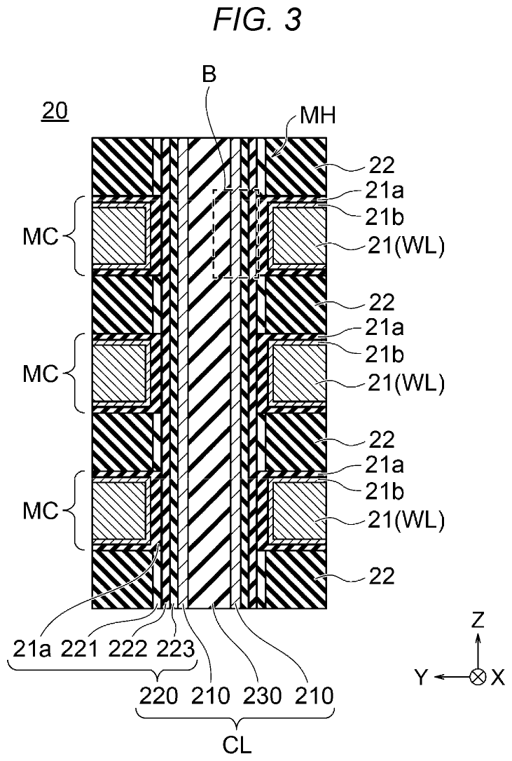

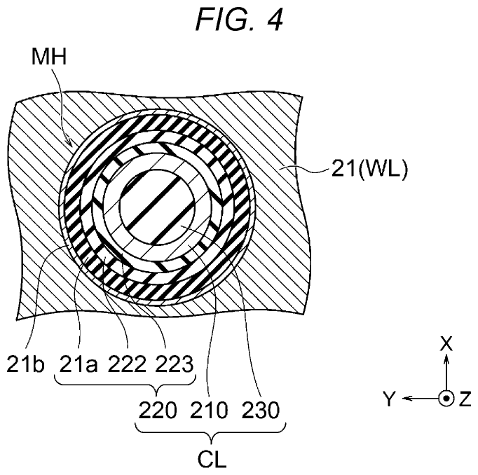

Each of FIGS. 3 and 4 is a cross-sectional view illustrating the memory cell having a three-dimensional structure. Each of the plurality of columnar bodies CL is provided in a memory hole MH provided in the stacked body 20. Each columnar body CL penetrates the stacked body 20 from the upper end of the stacked body 20 in the Z direction and is provided in the stacked body 20 and the semiconductor source layer BSL. Each of the plurality of columnar bodies CL includes the semiconductor body 210, a memory film 220, and a core layer 230. The columnar body CL includes the core layer 230 provided in the center thereof, the semiconductor body (semiconductor member) 210 provided around the core layer 230, and the memory film (charge storage member) 220 provided around the semiconductor body 210. The semiconductor body 210 extends in the stacking direction (in the Z direction) in the stacked body 20. The semiconductor body 210 is provided between the core layer 230 and a tunnel insulating film 223. The semiconductor body 210 is electrically connected to the semiconductor source layer BSL. The memory film 220 is provided between the semiconductor body 210 and the electrode film 21 and has a charge trapping portion. The plurality of columnar bodies CL, each of which is selected from each finger, are commonly connected to one bit line BL via the via 28 in FIG. 1. Each columnar body CL is provided, for example, in an area of the memory cell array 2m.

As illustrated in FIG. 4, the shape of the memory hole MH in the XY plane is, for example, a circle or an ellipse. A block insulating film 21a forming a part of the memory film 220 may be provided between the electrode film 21 and the insulating film 22. The block insulating film 21a is, for example, a silicon oxide film or a metal oxide film. One example of a metal oxide is an aluminum oxide. A barrier film 21b may be provided between the electrode film 21 and the insulating film 22 and between the electrode film 21 and the memory film 220. When the electrode film 21 is made of tungsten, for example, a stacked structure film of titanium nitride and titanium is selected as the barrier film 21b, for example. The block insulating film 21a prevents back tunneling of charges from the electrode film 21 to the memory film 220 side. The barrier film 21b improves the adhesion between the electrode film 21 and the block insulating film 21a.

The shape of the semiconductor body 210 serving as the semiconductor member is, for example, a bottomed cylindrical shape. For example, polysilicon is used for the semiconductor body 210. The semiconductor body 210 is, for example, n-type silicon. The semiconductor body 210 serves as a channel portion of each of a drain-side select transistor STD, the memory cell MC, and a source-side select transistor STS. One ends of the plurality of the semiconductor bodies 210 in the same memory cell array 2m are electrically commonly connected to the semiconductor source layer BSL.

A portion of the memory film 220 other than the block insulating film 21a is provided between an inner wall of the memory hole MH and the semiconductor body 210. The shape of the memory film 220 is, for example, a cylindrical shape. The plurality of memory cells MC have a storage area between the semiconductor body 210 and the electrode film 21 serving as the word line WL and are stacked in the Z direction. Each memory cell MC is provided corresponding to an intersection portion between the electrode film 21 and the columnar body CL. The memory film 220 includes, for example, a cover insulating film 221, a charge trapping film 222, and the tunnel insulating film 223. Each of the semiconductor body 210, the charge trapping film 222, and the tunnel insulating film 223 extends in the Z direction.

The cover insulating film 221 is provided between the insulating film 22 and the charge trapping film 222. The cover insulating film 221 contains, for example, silicon oxide. The cover insulating film 221 protects the charge trapping film 222 from being etched when a sacrifice film (not illustrated) is replaced with the electrode film 21 (a replacement process). The cover insulating film 221 may be removed from between the electrode film 21 and the memory film 220 in the replacement process. In this case, as illustrated in FIGS. 3 and 4, for example, the block insulating film 21a is not provided between the electrode film 21 and the charge trapping film 222. Furthermore, if the replacement process is not used to form the electrode film 21, the cover insulating film 221 may not be provided.

The charge trapping film 222 is provided between the tunnel insulating film 223 and the stacked body 20, and more specifically, the charge trapping film 222 is provided between the block insulating film 21a and the cover insulating film 221, and the tunnel insulating film 223. The charge trapping film 222 contains, for example, silicon nitride and has a trap site for trapping charges in the film. A portion of the charge trapping film 222, in which the portion is interposed between the electrode film 21 serving as the word line WL and the semiconductor body 210, forms a storage area of the memory cell MC as the charge trapping portion. A threshold voltage of the memory cell MC changes depending on presence or absence of charges in the charge trapping portion or an amount of charges trapped in the charge trapping portion. Accordingly, the memory cell MC stores information.

The tunnel insulating film 223 is provided between the semiconductor body 210 and the stacked body 20, and more specifically, the tunnel insulating film 223 is provided between the semiconductor body 210 and the charge trapping film 222. The tunnel insulating film 223 contains, for example, silicon oxide or silicon oxide and silicon nitride. The tunnel insulating film 223 is a voltage barrier between the semiconductor body 210 and the charge trapping film 222. For example, when an electron is injected from the semiconductor body 210 to the charge trapping portion (a write operation), and when a hole is injected from the semiconductor body 210 to the charge trapping portion (an erasing operation), the electron and the hole respectively pass through the voltage barrier of the tunnel insulating film 223 (tunneling).

The core layer 230 fills the interior space of the cylindrical semiconductor body 210. The shape of the core layer 230 is, for example, a columnar shape. The core layer 230 includes, for example, silicon oxide and is insulating.

As illustrated in FIG. 1, the columnar body CL is formed by dividing the columnar body CL into the columnar portions T1 and T2, but the configuration of the columnar portions T1 and T2 may be the configuration illustrated in FIGS. 3 and 4. The dummy columnar portion T2d is provided in the interlayer insulating film 25, but is formed at the same time as the columnar portion T2, and has the same configuration as that of the columnar body CL.

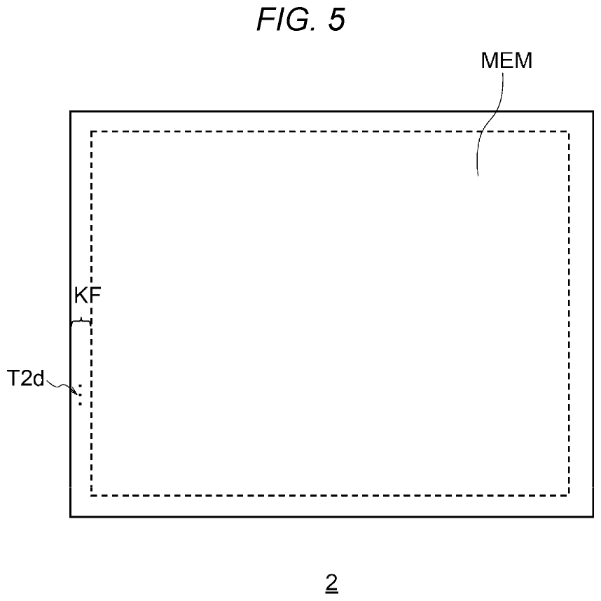

FIG. 5 is a schematic plan view illustrating a configuration example of the array chip 2 of the semiconductor memory device 1 according to the first embodiment. The memory cell array 2m and the like are provided in the center of the array chip 2. The dummy columnar portion T2d is provided at the outer edge portion KF of the array chip 2 and is provided around a memory area MEM.

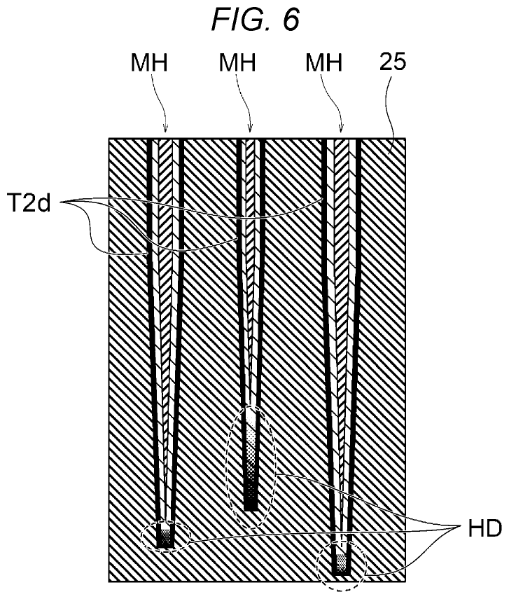

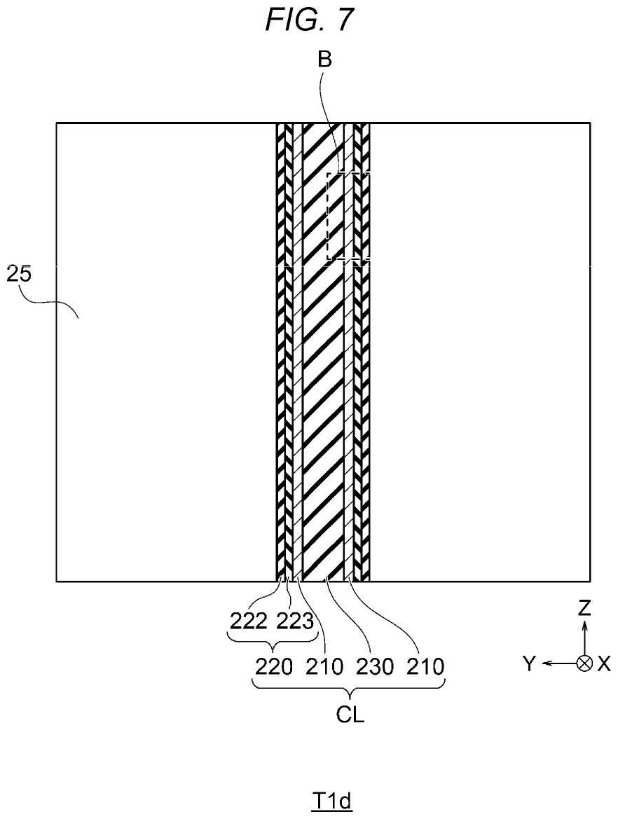

FIG. 6 is a cross-sectional view illustrating a configuration example of the dummy columnar portion T2d. FIG. 7 is a cross-sectional view illustrating a configuration example of one dummy columnar portion T2d.

As illustrated in FIG. 6, the dummy columnar portion T2d is provided at the outer edge portion KF and has the same configuration as that of the columnar portions T1 and T2. It is noted that as illustrated in FIG. 1, a lower portion of the columnar portion T2 reaches the semiconductor source layer BSL, and the semiconductor source layer BSL is in contact with a periphery of the lower portion of the columnar portion T2. Conversely, the dummy columnar portion T2d is provided in the interlayer insulating film 25, as illustrated in FIG. 6. The interlayer insulating film 25 is in contact with the dummy columnar portion T2d.

An impurity concentration of the semiconductor body 210 in the lower portion of the dummy columnar portion T2d is higher than an impurity concentration of the semiconductor body 210 of the memory cell MC in the columnar portions T1 and T2. The impurity concentration of the semiconductor body 210 at the bottom portion of the dummy columnar portion T2d (for example, a portion at which the memory hole MH of the dummy columnar portion T2d is blocked by deposition of the semiconductor body 210, that is, a portion at which the core layer 230 does not exist) is, for example, 1×10²⁰ cm⁻³ or higher. The impurity concentration other than the bottom portion of the dummy columnar portion T2d is, for example, 5×10¹⁹ cm⁻³ or lower, and is lower than the impurity concentration of the bottom portion of the dummy columnar portion T2d. The impurity concentration of the semiconductor body 210 of the memory cell MC in the columnar portions T1 and T2 is, for example, 5×10¹⁹ cm⁻³ or lower. The impurity is, for example, an n-type impurity (phosphorus and arsenic). The impurity concentration may be measured, for example, by energy dispersive X-ray analysis (EDX). The semiconductor body 210 of the memory cell MC in the columnar portions T1 and T2 is an area of the semiconductor body 210 that intersects the electrode film 21 functioning as the word line WL other than the source-side select gate SGS and the drain-side select gate SGD.

The entire semiconductor body 210 of the columnar portions T1 and T2 and the dummy columnar portion T2d is initially formed as, for example, an amorphous silicon film containing a high concentration impurity of 1×10²⁰ cm⁻³ or higher. After the semiconductor body 210 is crystallized into a polysilicon film, an impurity is extracted from the semiconductor body 210. In this process, since the lower portion of the dummy columnar portion T2d is filled with the semiconductor body 210, the impurity in the semiconductor body 210 is not sufficiently extracted. Therefore, the impurity concentration of the semiconductor body 210 at the bottom portion of the dummy columnar portion T2d remains high, and the same is higher than the impurity concentration of the semiconductor body 210 of the columnar portions T1 and T2.

As illustrated in FIG. 7, the configuration of the dummy columnar portion T2d may be the same as that of the columnar body CL. Therefore, the dummy columnar portion T2d includes the core layer 230, the semiconductor body 210, and the memory film 220 in the memory hole MH.

The core layer 230 extends in the Z direction in the interlayer insulating film 25. The semiconductor body 210 is provided between the core layer 230 and the interlayer insulating film 25 and is provided around the core layer 230. The memory film 220 is provided between the semiconductor body 210 and the interlayer insulating film 25 and is provided around the semiconductor body 210. The memory film 220 includes the tunnel insulating film 223 and the charge trapping film 222. The interlayer insulating film 25 is provided around the memory film 220. The core layer 230 is formed, for example, in a cylindrical shape. Each of the semiconductor body 210 and the memory film 220 is, for example, formed in a cylindrical shape.

Similarly to the semiconductor body 210 of the columnar portions T1 and T2 of the columnar body CL, the semiconductor body 210 is made of, for example, polysilicon having a relatively large crystal particle diameter.

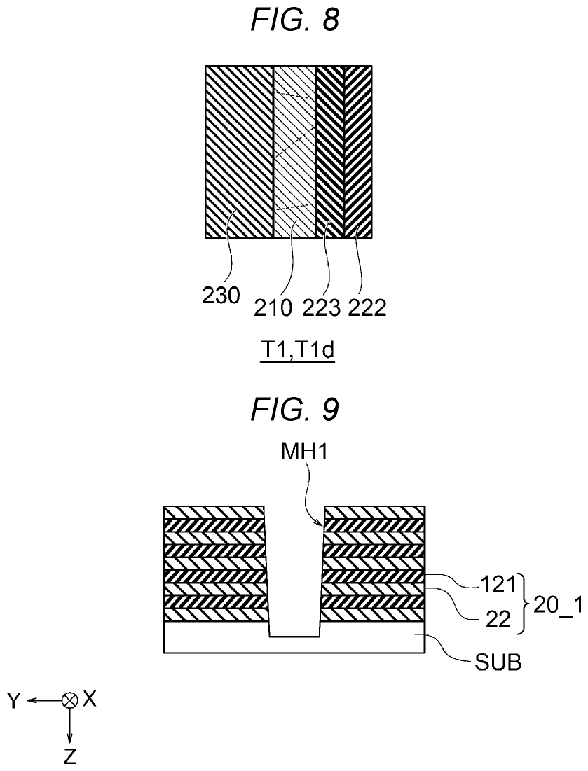

FIG. 8 is a cross-sectional view illustrating the semiconductor body 210 of the columnar portions T1 and T2 and the dummy columnar portion T2d according to the first embodiment and a periphery thereof. FIG. 8 illustrates a portion indicated by a broken line frame B in FIGS. 3 and 7.

The semiconductor body 210 is a channel portion of each of the drain-side select transistor STD, the memory cell MC, and the source-side select transistor STS. As described above, the semiconductor body 210 is formed of, for example, n-type silicon. The impurity concentration contained in the semiconductor body 210 is lower than the impurity concentration contained in the semiconductor body 210 at the bottom portion of the dummy columnar portion T2d. The impurity is the n-type impurity (for example, phosphorus and arsenic).

For example, the semiconductor body 210 is formed of an amorphous silicon film at the beginning of film formation and is crystallized into a polysilicon film by performing annealing treatment at a temperature of 800° C. or higher. At this time, when the n-type impurity is introduced into the amorphous silicon film of the semiconductor body 210 at a high concentration (for example, 1×10²⁰ cm⁻³ or higher), as compared with an undoped amorphous silicon film, the crystal particle diameter of the polysilicon film after the annealing treatment becomes larger. As compared with a case in which an undoped amorphous silicon film is used in the semiconductor body 210, when a doped polysilicon film is used, the crystal particle diameter of the polysilicon film increases by about 40%. For example, when the undoped amorphous silicon film is used in the semiconductor body 210, the particle diameter of the polysilicon film after the annealing treatment is, for example, about 50 nm or less. Conversely, in the case of using an amorphous silicon film in which the n-type impurity is introduced into the semiconductor body 210, the particle diameter of the polysilicon film after the annealing treatment is, for example, about 80 nm or more.

A grain boundary between crystals traps a carrier and becomes a voltage barrier, which causes deterioration in carrier mobility. As the particle diameter of the polysilicon film of the semiconductor body 210 is larger, the density of the grain boundary becomes smaller and, as such, the carrier mobility of the semiconductor body 210 is improved.

Therefore, in the case of using the amorphous silicon film in which the n-type impurity is introduced into the semiconductor body 210, as compared with a case in which the undoped amorphous silicon film is used, the carrier mobility of the semiconductor body 210 after the annealing treatment is increased.

Meanwhile, for example, when a high concentration impurity of 1×10²⁰ cm⁻³ or higher exists in the semiconductor body 210, a carrier concentration in the semiconductor body 210 is also increased. In this case, the semiconductor body 210 has a low resistance and cannot function as a channel portion.

Therefore, in the present embodiment, after the crystal particle diameter of the polysilicon film is increased by the annealing treatment, the impurity concentration in the semiconductor body 210 is reduced. The impurity concentration in the semiconductor body 210 is reduced by diffusion through the annealing treatment. The impurity concentration existing in the semiconductor body 210 is reduced to, for example, 5×10¹⁹ cm⁻³ or lower. Accordingly, the semiconductor body 210 can function normally as a channel portion of the memory cell MC while being formed of polysilicon having a relatively large particle diameter. That is, it is possible to improve the carrier mobility of the semiconductor body 210 and increase a cell current of the memory cell MC.

When the impurity concentration of the semiconductor body 210 is 5×10¹⁹ cm⁻³ or lower, resistivity of the semiconductor body 210 is equal to or greater than 1.5×10⁻³ Ω·cm. That is, resistivity of the channel portion of the memory cell MC according to the first embodiment is equal to or greater than 1.5×10⁻³ Ω·cm.

It is noted that the particle diameter of a crystal or the like is performed using particle diameter analysis by automated crystal orientation mapping in TEM (ACOM-TEM) analysis. Twin crystals are treated as a grain boundary. If there are two or more consecutive measurement points within an azimuth angle difference (5°), the measurement points are treated as the same grain. An average particle diameter d is calculated by the following mathematical formula, where the total number of particles is defined as N, and an area ratio and a particle diameter (a circular equivalent diameter) of individual particles are respectively defined as Ai and di.

$$d = {\sum }_{i = 1}^{N} Ai \times di$$

Next, a manufacturing method of the semiconductor memory device 1 according to the present embodiment will be described.

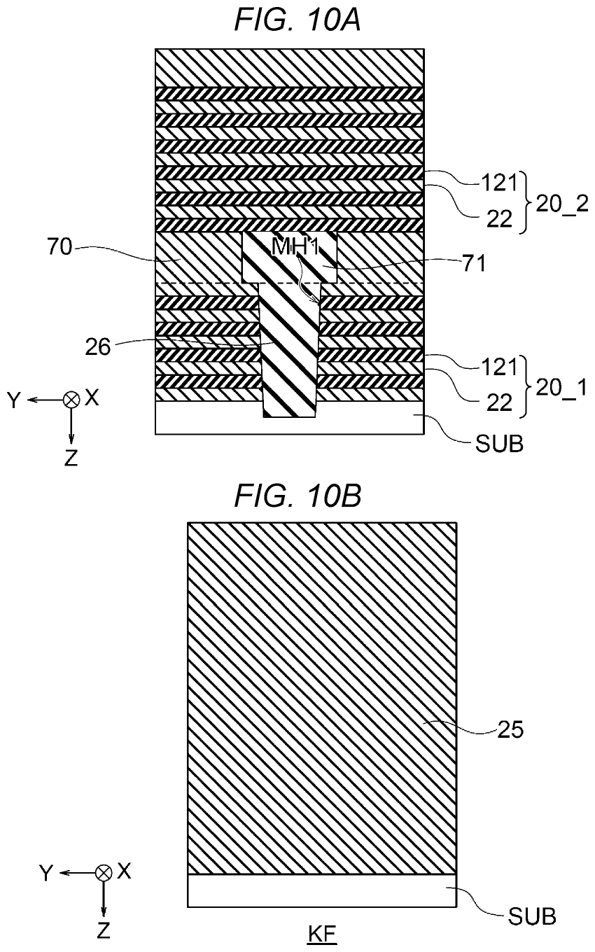

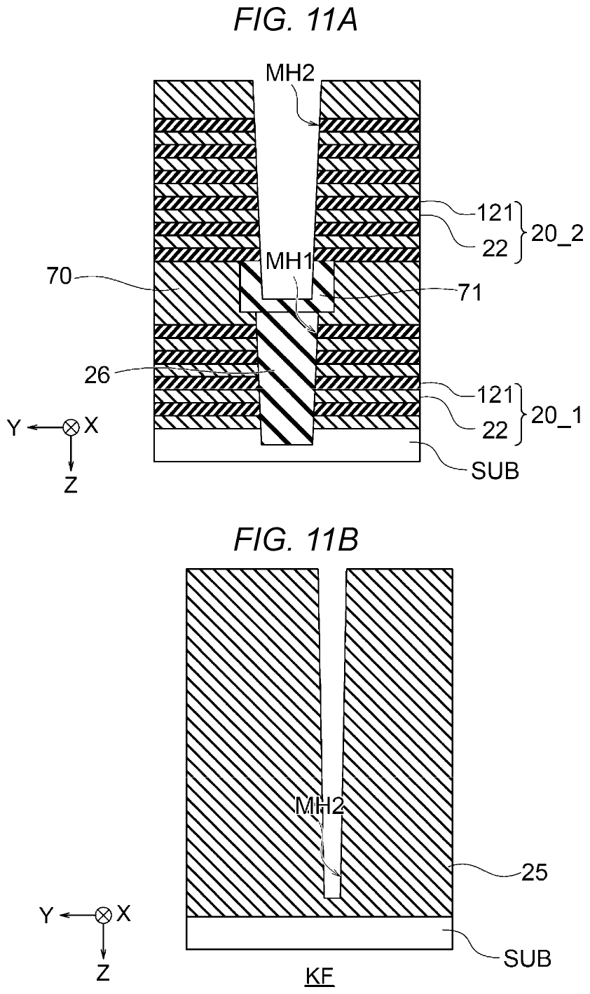

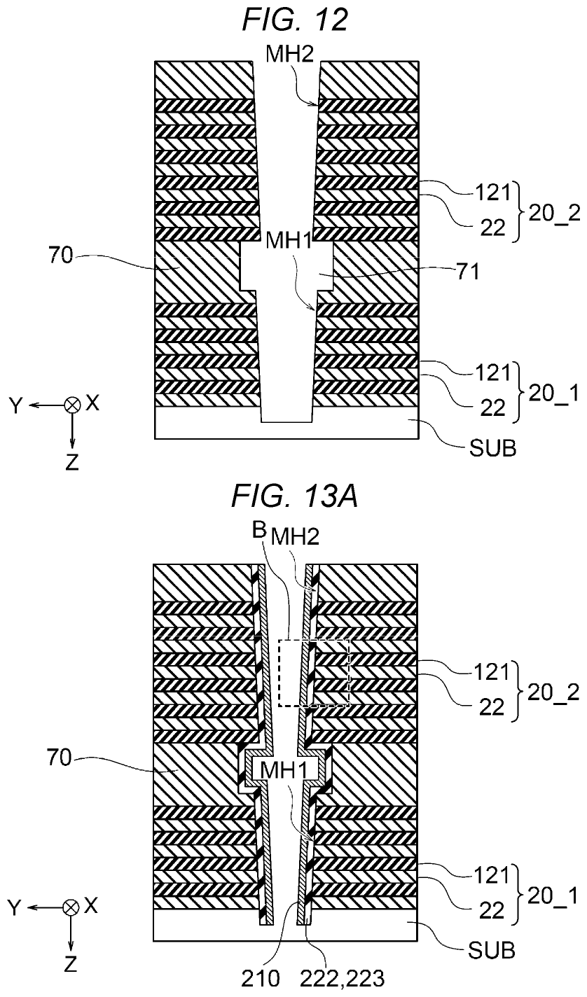

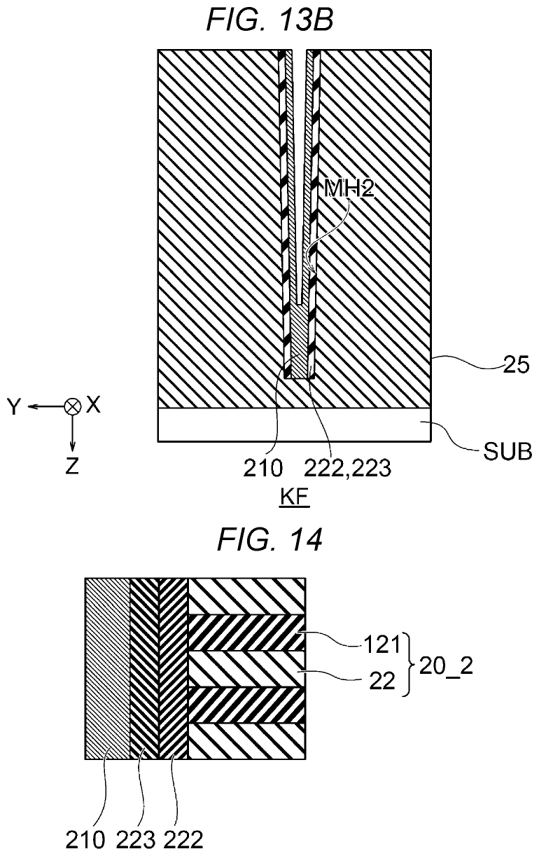

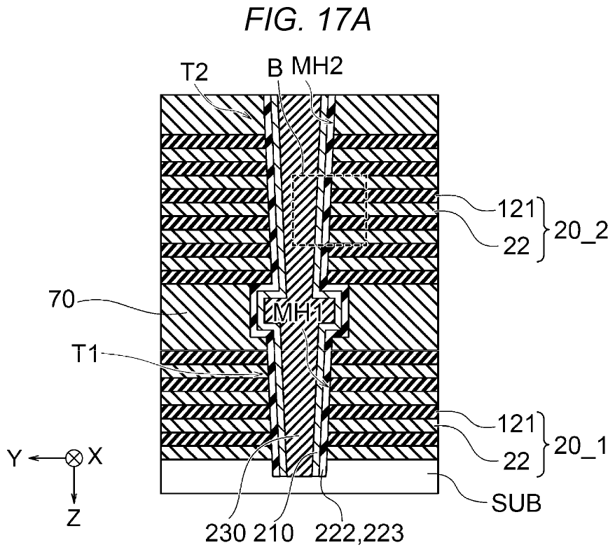

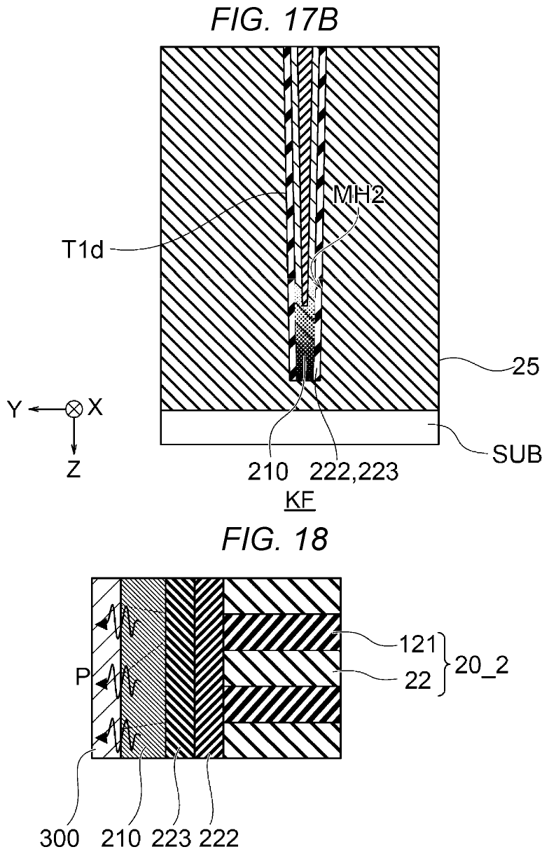

FIGS. 9 to 17B are cross-sectional views illustrating an example of the manufacturing method of the semiconductor memory device 1 according to the first embodiment. FIG. 9, FIG. 10A, FIG. 11A, FIG. 12, FIG. 13A, and FIG. 17A illustrate cross sections of the columnar portions T1 and T2. FIG. 10B, FIG. 11B, FIG. 13B, and FIG. 17B illustrate cross sections of the dummy columnar portion T2d. It is noted that, in FIGS. 9 to 17B, the vertical direction (the Z direction) of the structure is reversely displayed with respect to FIG. 1.

First, as illustrated in FIG. 9, the insulating film 22 and a sacrifice film 121 are alternately stacked in the Z direction on a substrate SUB to form a stacked body 20_1. The substrate SUB may be, for example, a semiconductor substrate such as a silicon substrate or may be the semiconductor source layer BSL. In the insulating film 22, for example, an insulating film such as a silicon oxide film is used. In the sacrifice film 121, for example, an insulating film such as a silicon nitride film is used. The sacrifice film 121 is a material that can be selectively etched with respect to the insulating film 22 in order to be replaced with the electrode film 21 in a subsequent process.

Conversely, although not illustrated, the stacked body 20_1 is not formed on the substrate SUB at the outer edge portion KF.

Next, a memory hole MH1 is formed in the stacked body 20_1 and the interlayer insulating film 25 using lithography technology and etching technology. The memory hole MH1 extends in the Z direction in the stacked body 20_1 and reaches the substrate SUB.

Next, as illustrated in FIG. 10A, a sacrifice film 26 is buried in the memory hole MH1. In the sacrifice film 26, for example, a material capable of being selectively etched with respect to the insulating film 22 and the sacrifice film 121, such as polysilicon, is used.

Next, an intermediate layer 70 is formed on the stacked body 20_1 and the sacrifice film 26. By using lithography technology and etching technology, the intermediate layer 70 is processed to remove the intermediate layer 70 of the sacrifice film 26, and a sacrifice film 71 is buried on the sacrifice film 26.

Next, the insulating film 22 and the sacrifice film 121 are further alternately stacked on the intermediate layer 70 and the sacrifice film 71 in the Z direction to form a stacked body 20_2. In this manner, the structure illustrated in FIG. 10A is obtained.

Meanwhile, as illustrated in FIG. 10B, the interlayer insulating film 25 is formed on the substrate SUB at the outer edge portion KF. For example, a silicon oxide film is used in the interlayer insulating film 25.

Next, as illustrated in FIG. 11A, a memory hole MH2 is formed in the stacked body 20_2 using lithography technology and etching technology. The memory hole MH2 extends in the Z direction in the stacked body 20_2 and reaches the sacrifice film 71 on the memory hole MH1. The sacrifice film 71 functions as an etching stopper in the process of forming the memory hole MH2.

At this time, as illustrated in FIG. 11B, the memory hole MH2 is similarly formed in the interlayer insulating film 25 at the outer edge portion KF. The memory hole MH2 extends in the Z direction in interlayer insulating film 25. However, since the memory hole MH1 is not formed at the outer edge portion KF, the memory hole MH2 is formed in the interlayer insulating film 25 and does not reach the substrate SUB.

Next, as illustrated in FIG. 12, the sacrifice film 26 is selectively removed via the memory hole MH2. Accordingly, the memory holes MH1 and MH2 are formed as one memory hole extending in the Z direction in the stacked bodies 20_1 and 20_2.

Next, as illustrated in FIGS. 13A and 13B, the charge trapping film 222, the tunnel insulating film 223, and the semiconductor body 210 are deposited in this order on inner walls of the memory holes MH1 and MH2. The charge trapping film 222, the tunnel insulating film 223, and the semiconductor body 210 are also formed in the memory hole MH2 of the outer edge portion KF. For example, silicon nitride is used in the charge trapping film 222. For example, a silicon oxide film is used in the tunnel insulating film 223. In the semiconductor body 210, for example, an amorphous silicon film doped with the n-type impurity is used. The amorphous silicon film of the semiconductor body 210 contains phosphorus or arsenic as the n-type impurity. The n-type impurity concentration of the semiconductor body 210 is, for example, 1×10²⁰ cm⁻³ or higher, which is a relatively high concentration.

Next, the annealing treatment is performed on a structure illustrated in FIG. 14. It is noted that FIGS. 14 to 16 illustrate cross sections of a portion indicated by a broken line frame B in FIG. 13A. The semiconductor body 210 of the dummy columnar portion T2d at the outer edge portion KF is also processed in the same manner and at the same time.

As illustrated in FIG. 14, the semiconductor body 210 is formed as an amorphous silicon film at the beginning of film formation.

Next, as illustrated in FIG. 15, the amorphous silicon film of the semiconductor body 210 is crystallized by performing the annealing treatment and is transformed into a polysilicon film. At this time, since the semiconductor body 210 contains a high concentration n-type impurity of 1×10²⁰ cm⁻³ or higher, the semiconductor body 210 is transformed into a polysilicon film having a relatively large particle diameter. For example, the semiconductor body 210 is an amorphous silicon film having a phosphorus concentration of 1×10²⁰ cm⁻³ cm or higher, and when the annealing treatment is performed at a temperature of about 800° C. or higher, the particle diameter of the polysilicon film after the annealing treatment is, for example, about 80 nm or more. When the particle diameter of the semiconductor body 210 is large, the density of the grain boundary deteriorates and, as such, the carrier mobility of the semiconductor body 210 is improved, and the cell current of the memory cell MC can be increased.

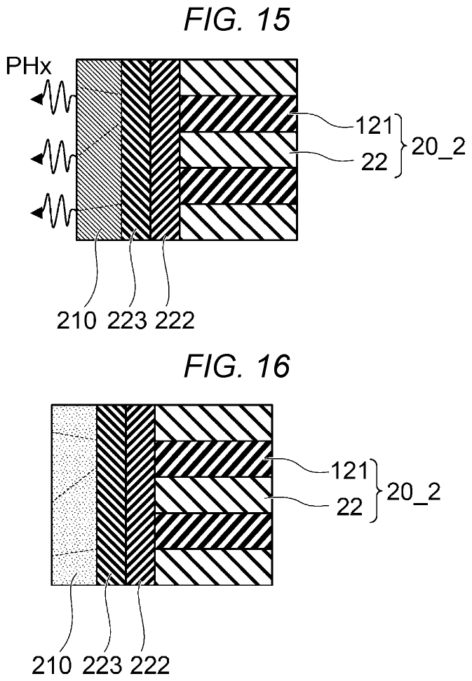

Next, as illustrated in FIGS. 15 and 16, the annealing treatment causes diffusion of an impurity contained in the polysilicon film of the semiconductor body 210. For example, the annealing treatment is performed at a temperature of about 800° C. or higher. Through the annealing treatment, for example, phosphorus in the semiconductor body 210 becomes hydrogen phosphide (PHx (x is a positive integer)) and is diffused (desorbed) to the outside. By diffusing the impurity, the impurity concentration existing in the semiconductor body 210 can be reduced, for example, from 1×10²⁰ cm⁻³ or higher to 5×10¹⁹ cm⁻³ or lower (it is noted that the impurity concentration existing in the semiconductor body 210 is not reduced below a detection limit). Accordingly, the semiconductor body 210 is formed of a polysilicon film having a relatively large particle diameter and has a relatively low impurity concentration. As a result, the semiconductor body 210 can function normally as a channel portion of the memory cell MC while improving the carrier mobility.

Meanwhile, as illustrated in FIG. 13B, at the outer edge portion KF, the memory hole MH1 is not formed, and the memory hole MH2 is formed deep (long) in the interlayer insulating film 25, and the bottom portion thereof is thinner than the bottom portion of the columnar portion T2. Therefore, the semiconductor body 210 is easily buried at the bottom portion of the memory hole MH2 of the outer edge portion KF. Therefore, in the annealing treatment, at the bottom portion of the memory hole MH2 of the outer edge portion KF, the impurity contained in the polysilicon film of the semiconductor body 210 is not sufficiently diffused and is highly likely to remain at a high concentration. Therefore, as illustrated in FIG. 17B, at the bottom portion of the memory hole MH2 of the outer edge portion KF, an impurity having a high concentration of, for example, 1×10²⁰ cm⁻³ or higher remains in the polysilicon film of the semiconductor body 210.

Next, as illustrated in FIGS. 17A and 17B, the core layer 230 is buried in the semiconductor body 210 in the memory holes MH1 and MH2. In this manner, the columnar body CL is formed. As illustrated in FIG. 17B, at the bottom portion of the memory hole MH2 of the outer edge portion KF, an impurity having a high concentration remains in the polysilicon film of the semiconductor body 210.

Next, the slit ST illustrated in FIG. 1 is formed, and the sacrifice film 121 illustrated in FIG. 17A is removed through the slit ST. Furthermore, a material (for example, tungsten) of the electrode film 21 is buried in the space formed after the sacrifice film 121 is removed. As a result, the sacrifice films 121 of the stacked bodies 20_1 and 20_2 are replaced with the electrode films 21, and the stacked body 20 in FIG. 1 is formed.

An insulating film such as a silicon oxide film is formed on the inner wall of the slit ST, and a conductive material such as tungsten is buried in the insulating film in the slit ST. Accordingly, the source wiring LI illustrated in FIG. 1 is formed. The source wiring LI is electrically connected to the semiconductor source layer BSL.

Next, a multilayer wiring layer (not shown) and the like are formed on the columnar body CL. As a result, the array chip 2 is completed.

Next, as illustrated in FIG. 1, the CMOS chip 3 formed in a separate process is bonded to the array chip 2.

Next, the semiconductor source layer BSL is exposed using a CMP method. The metal layer 40 and the bonding pad 50 are formed on the semiconductor source layer BSL. As a result, the semiconductor memory device 1 according to the present embodiment is completed.

According to the present embodiment, in the film formation process of the semiconductor body 210, for example, an amorphous silicon film containing an n-type impurity having a high concentration of 1×10²⁰ cm⁻³ or higher is formed and is transformed into a polysilicon film formed of a crystal having a large particle diameter during the annealing treatment. Furthermore, the annealing treatment causes the n-type impurity of the polysilicon film in the semiconductor body 210 to be diffused to the outside. Accordingly, an impurity concentration existing in the semiconductor body 210 is reduced to, for example, 5×10¹⁹ cm⁻³ or lower. Therefore, the semiconductor body 210 is formed of a polysilicon film having a large particle diameter and can function normally as a channel portion of the memory cell MC. As a result, the carrier mobility of the semiconductor body 210 can be improved and the cell current of the memory cell MC can be increased.

Meanwhile, as illustrated in FIG. 17B, at the outer edge portion KF, the memory hole MH2 is formed deeply (long) in the interlayer insulating film 25, and the bottom portion thereof is thinner than the bottom portion of the columnar portion T2. Therefore, at the bottom portion of the memory hole MH2 of the outer edge portion KF, an impurity having a high concentration of, for example, 1×10²⁰ cm⁻³ or higher remains in the polysilicon film of the semiconductor body 210.

### First Modification

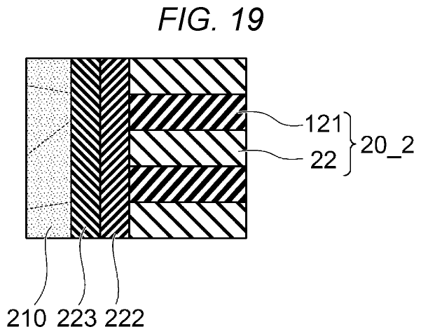

FIGS. 18 and 19 are cross-sectional views illustrating an example of a manufacturing method of the semiconductor memory device 1 according to a first modification of the first embodiment. In the first modification, an impurity contained in the polysilicon film of the semiconductor body 210 is reduced using a sacrifice film 300.

After processes illustrated in FIGS. 9 to 15 are performed, the sacrifice film 300 is formed in the semiconductor body 210, as illustrated in FIG. 18. In the sacrifice film 300, a material film that is not doped with an impurity, such as undoped amorphous silicon, is used. An impurity concentration of the sacrifice film 300 is lower than an impurity concentration contained in the semiconductor body 210 at this time.

Next, the impurity contained in the polysilicon film of the semiconductor body 210 is diffused into the sacrifice film 300 by annealing treatment. For example, the annealing treatment is performed at a temperature of about 800° C. or higher. As a result, the impurity is diffused from the polysilicon film of the semiconductor body 210 into the undoped amorphous silicon film of the sacrifice film 300, as illustrated in FIG. 18.

Next, as illustrated in FIG. 19, the sacrifice film 300 is removed by an etching method. Thereby, the impurity diffused into the sacrifice film 300 can be removed from the semiconductor body 210.

When the impurity concentration contained in the semiconductor body 210 is still high, the sacrifice film 300 is newly formed in the semiconductor body 210. Similarly, the annealing treatment and the etching processing may be repeatedly performed to remove the impurity from the semiconductor body 210. That is, a process from formation of the sacrifice film 300 to removal of the sacrifice film 300 may be repeatedly performed a plurality of times. Thereafter, the core layer 230 is buried.

As a result, as illustrated in FIG. 19, the impurity concentration existing in the semiconductor body 210 can be reduced, for example, from 1×10²⁰ cm⁻³ or higher to 5×10¹⁹ cm⁻³ or lower. Accordingly, the semiconductor body 210 is formed of a polysilicon film having a relatively large particle diameter and has a relatively low impurity concentration. As a result, the semiconductor body 210 can function normally as a channel portion of the memory cell MC while improving the carrier mobility.

In addition, the configuration and the manufacturing method of the first modification may be the same as the configuration and the manufacturing method of the first embodiment. Accordingly, the first modification can obtain the same effects as those of the first embodiment.

### Second Modification

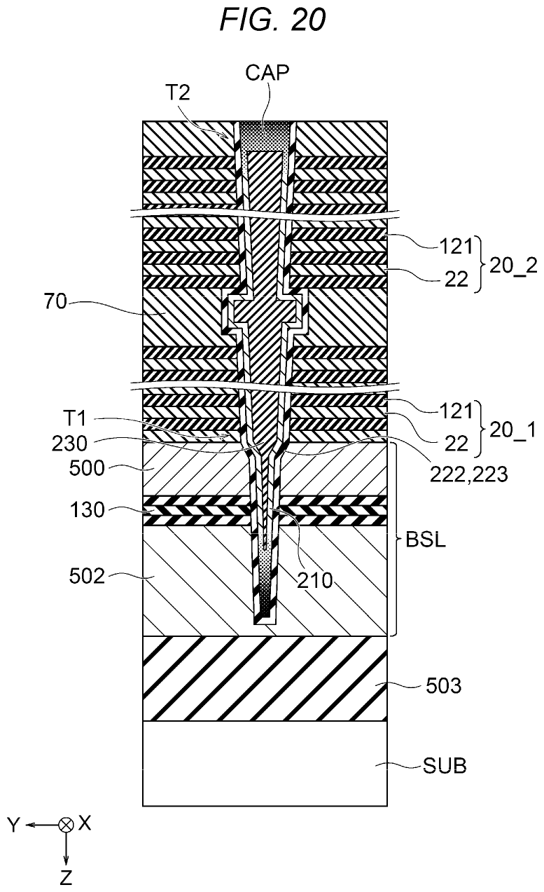

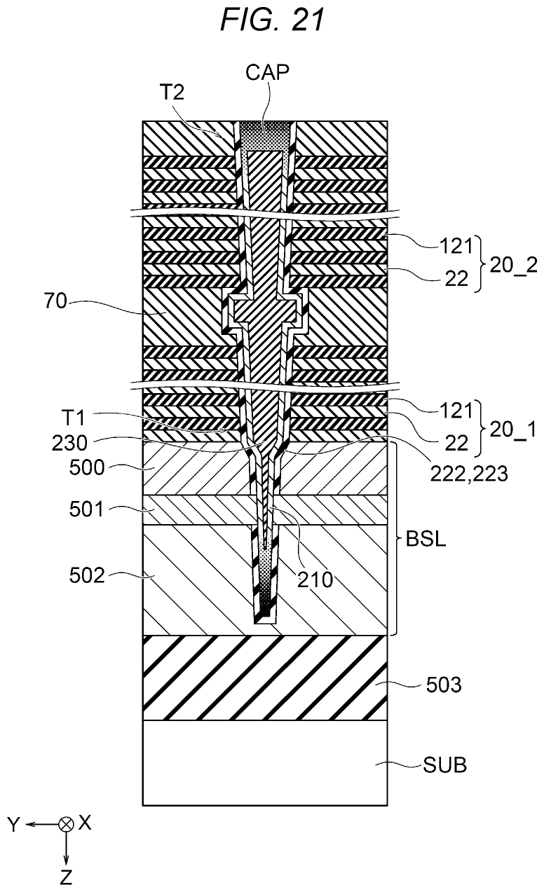

FIGS. 20 and 21 are cross-sectional views illustrating a configuration example of the semiconductor memory device 1 according to a second modification of the first embodiment. In the second modification, the stacked body 20_1 is not directly formed on the substrate SUB, and an insulating film 503 and a semiconductor source layer BSL made of, for example, a polysilicon film are provided between the substrate SUB and the stacked body 20_1. As shown in FIG. 21, the semiconductor source layer BSL is formed of, in order from the bottom, a semiconductor film 502, a semiconductor film 501, and a semiconductor film 500, each of which is made of, for example, a polysilicon film.

A manufacturing method of the second modification is performed as follows. As shown in FIG. 20, a sacrifice film 130 is formed in a formation area of the semiconductor film 501 before the stacked bodies 20_1 and 20_2 are formed. For example, a silicon oxide film or a silicon nitride film is used for the sacrifice film 130. Next, the stacked bodies 20_1 and 20_2 and the columnar body CL are formed. The columnar body CL is formed in the same manner as that of the first embodiment or the first modification. Therefore, the semiconductor body 210 is formed of an amorphous silicon film having an impurity of a high concentration of 1×10²⁰ cm⁻³ or higher, and then the same is transformed into a polysilicon film having an impurity concentration or a carrier concentration of 5×10¹⁹ cm⁻³ or lower. After the core layer 230 is buried in the memory holes MH1 and MH2, the core layer 230 is etched back, and a silicon cap layer CAP is buried on the outer layer 230. The silicon cap layer CAP is electrically connected to the semiconductor body 210 and is also electrically connected to the bit line BL (the wiring 23 in FIG. 1) located thereabove. The silicon cap layer CAP electrically connects the bit line BL to the semiconductor body 210 (the channel portion of the memory cell MC). Therefore, a conductive doped polysilicon film or the like is used in the silicon cap layer CAP.

Thereafter, the sacrifice film 130 is removed through the slit ST illustrated in FIG. 2, and the charge trapping film 222 and the tunnel insulating film 223 exposed by the removal of the sacrifice film 130 are also removed. Accordingly, a side surface of the semiconductor body 210 is exposed. As illustrated in FIG. 21, a material of the semiconductor film 501 (for example, a conductive material such as doped polysilicon) is buried in the area where the sacrifice film 130 is present. Thereby, the semiconductor film 501 is in direct contact with the side surface of the semiconductor body 210. In this manner, in the present second modification, the material of the sacrifice film 130 is replaced with the material of the semiconductor film 501, thereby forming the semiconductor film 501 electrically connected to the semiconductor body 210.

The semiconductor film 501 is, for example, the doped polysilicon film containing phosphorus, which is the n-type impurity. In this case, the impurity in the semiconductor film 501 is diffused into the semiconductor body 210, and the impurity concentration of the semiconductor body 210 at the bottom portion of the columnar portion T1 may become the high concentration of 1×10²⁰ cm⁻³ or higher. In this case, the impurity concentration of the semiconductor body 210 at the bottom portion of the columnar portion T1 becomes higher than the impurity concentration of the semiconductor body 210 that intersects the electrode film 21 other than the source-side select gate SGS and the drain-side select gate SGD.

Meanwhile, in an area A far from the slit ST illustrated in FIG. 2, the sacrifice film 130 may be left without being replaced with the semiconductor film 501. The area A is located at a center location between two adjacent slits ST or located in the vicinity thereof. In this case, the structure illustrated in FIG. 20 partially remains. In the second modification, as illustrated in FIG. 17B, an impurity may remain at the bottom portion of the first columnar portion T1 at a high concentration of 1×10²⁰ cm⁻³ or higher. In this case, although the impurity in the semiconductor film 501 is not diffused into the semiconductor body 210, the impurity concentration at the bottom portion of the first columnar portion T1 becomes a high concentration of 1×10²⁰ cm⁻³ or higher. Therefore, in this case as well, the impurity concentration of the semiconductor body 210 at the bottom portion of the columnar portion T1 becomes higher than the impurity concentration of the semiconductor body 210 that intersects the electrode film 21 other than the source-side select gate SGS and the drain-side select gate SGD.

### Second Embodiment

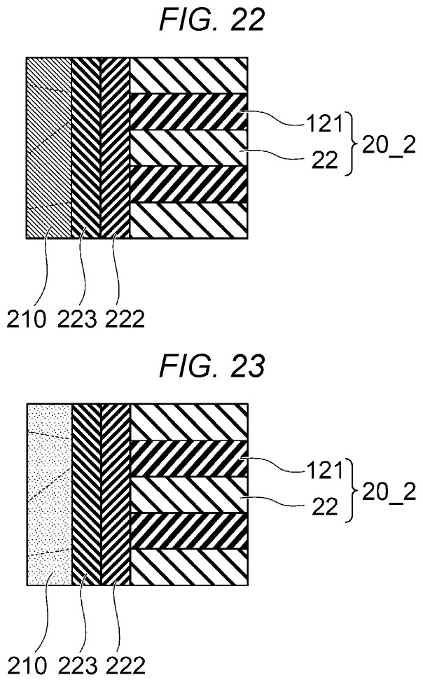

FIGS. 22 and 23 are cross-sectional views illustrating an example of a manufacturing method of the semiconductor memory device 1 according to a second embodiment. In the second embodiment, a carrier concentration (a mobile electron concentration) contained in the semiconductor body 210 is reduced by hydrogenation treatment. The carrier concentration contained in the semiconductor body 210 is reduced by the hydrogenation treatment. The hydrogenation treatment hardly changes the impurity concentration of semiconductor body 210 (the same level as that before hydrogeneration treatment), but can reduce the carrier concentration. It is noted that FIGS. 22 and 23 illustrate a portion indicated by the broken line frame B in FIGS. 3 and 7.

The semiconductor body 210 is a channel portion of each of the drain-side select transistor STD, the memory cell MC, and the source-side select transistor STS. As described above, the semiconductor body 210 is formed of, for example, n-type silicon. The carrier concentration contained in the semiconductor body 210 is lower than the concentration of the n-type impurity (for example, phosphorus and arsenic). An impurity is the n-type impurity (for example, phosphorus and arsenic).

A carrier is a mobile electron or a mobile hole in the semiconductor body 210 and is generated when an introduced impurity is activated by the annealing treatment or the like. The carrier concentration is the concentration of the impurity activated in this manner, or the concentration of the mobile electron or the mobile hole. An impurity in an inactive state does not provide the mobile electron or the mobile holes in the semiconductor body 210. Therefore, when the impurity is inactivated, the impurity concentration becomes high but the carrier concentration becomes low. In the present embodiment, the carrier is an electron.

For example, when the n-type impurity (for example, phosphorus and arsenic) in the semiconductor body 210 is inactivated (neutralized) by the hydrogenation treatment, even if the n-type impurity concentration in the semiconductor body 210 is high, the carrier concentration can be kept relatively low. For example, the n-type impurity is introduced into the semiconductor body 210 at a high concentration of 1×10²⁰ cm⁻³ or higher. Thereafter, the semiconductor body 210 is subjected to the hydrogenation treatment by PIO ( . . . ) oxidation or the like, thereby making it possible to cause the carrier concentration (mobile electron concentration) in the semiconductor body 210 to be reduced to a low concentration of 5×10¹⁹ cm⁻³ or lower.

For example, the semiconductor body 210 is formed of an amorphous silicon film at the beginning of film formation and is crystallized into a polysilicon film by performing the annealing treatment at a temperature of about 800° C. or higher. At this time, when the n-type impurity is introduced into the amorphous silicon film of the semiconductor body 210 at a high concentration (for example, 1×10²⁰ cm⁻³ or higher), as compared with an undoped amorphous silicon film, the crystal particle diameter of the polysilicon film after the annealing treatment becomes about 40% larger. For example, when the undoped amorphous silicon film is used in the semiconductor body 210, the particle diameter of the polysilicon film after the annealing treatment is, for example, about 50 nm or less. Conversely, in the case of using an amorphous silicon film in which the n-type impurity is introduced into the semiconductor body 210, the particle diameter of the polysilicon film after the annealing treatment is, for example, about 80 nm or more.

As a result, in the case of using the amorphous silicon film in which the n-type impurity is introduced into the semiconductor body 210, as compared with a case in which the undoped amorphous silicon film is used, the carrier mobility of the semiconductor body 210 after the annealing treatment is increased.

Meanwhile, for example, when a high concentration impurity of 1×10²⁰ cm⁻³ or higher exists in the semiconductor body 210, the carrier concentration in the semiconductor body 210 is also increased. In this case, the semiconductor body 210 has a low resistance and cannot function as a channel portion.

Therefore, in the second embodiment, the impurity in the semiconductor body 210 is inactivated by the hydrogenation treatment. In the case of the n-type impurity, the n-type impurity (for example, phosphorus and arsenic) is inactivated (neutralized) using a PIO oxidation method or the like. Accordingly, the carrier concentration existing in the semiconductor body 210 can be reduced to, for example, 5×10¹⁹ cm⁻³ or lower. Consequently, the semiconductor body 210 can function normally as a channel portion while being formed of polysilicon having a relatively large particle diameter. That is, it is possible to improve the carrier mobility of the semiconductor body 210 and increase the cell current of the memory cell MC.

When the carrier concentration of the semiconductor body 210 is 5×10¹⁹ cm⁻³ or lower, the resistivity of the semiconductor body 210 is equal to or greater than 1.5×10⁻³ Ω·cm. That is, the resistivity of the channel portion of the memory cell MC according to the second embodiment is equal to or greater than 1.5×10⁻³ Ω·cm.

Next, the manufacturing method of the semiconductor memory device 1 according to the second embodiment will be described.

After performing the processes illustrated in FIGS. 9 to 14, the structure shown in FIG. 14 is subjected to radical treatment using atomic hydrogen (hereinafter, also referred to as the hydrogenation treatment). The hydrogenation treatment of the semiconductor body 210 using wet oxidation inactivates (neutralizes) the n-type impurity, as illustrated in FIGS. 22 and 23. Accordingly, the carrier concentration existing in the semiconductor body 210 can be reduced from, for example, 1×10²⁰ cm⁻³ to 5×10¹⁹ cm⁻³ or lower. Thereby, the semiconductor body 210 is formed of a polysilicon film having a relatively large particle diameter and has a relatively low carrier concentration. As a result, the semiconductor body 210 can function normally as a channel portion of the memory cell MC while improving the carrier mobility.

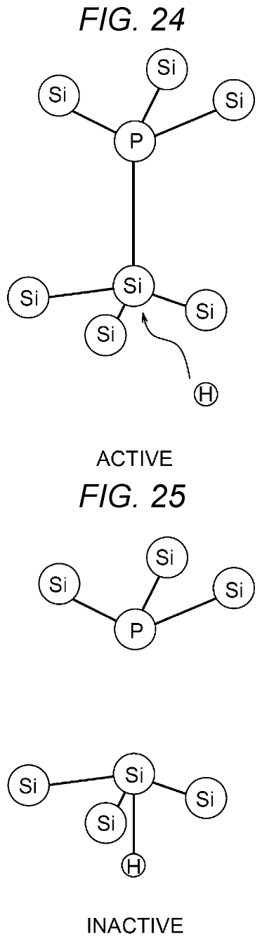

FIGS. 24 and 25 are conceptual diagrams illustrating the hydrogenation treatment. FIG. 24 illustrates the state of the semiconductor body 210 before the hydrogenation treatment. FIG. 25 illustrates the state of the semiconductor body 210 after the hydrogenation treatment. As illustrated in FIG. 24, an impurity P (phosphorus) is introduced into silicon Si of a polysilicon film. Before the hydrogenation treatment, the impurity P is activated and bonded to the silicon Si. As illustrated in FIG. 25, when the hydrogenation treatment is performed by the PIO oxidation method or the like, the impurity P is cut off from a part of the silicon Si, and the silicon Si is combined with hydrogen H. Accordingly, the impurity P is inactivated. By inactivating the impurity P, the concentration of the impurity P remains relatively high and the carrier concentration is lowered. Thereby, the carrier concentration in the semiconductor body 210 can be lowered while the particle diameter of the polysilicon film of the semiconductor body 210 is increased.

Thereafter, the semiconductor memory device according to the second embodiment is completed through the processes described with reference to FIG. 17A, FIG. 17B, and FIG. 1.

According to the second embodiment, the impurity in the semiconductor body 210 is inactivated by the hydrogenation treatment, thereby reducing the carrier concentration. Accordingly, the semiconductor body 210 can function normally as a channel portion while being formed of polysilicon having a relatively large particle diameter. That is, it is possible to improve the carrier mobility of the semiconductor body 210 and increase the cell current of the memory cell MC.

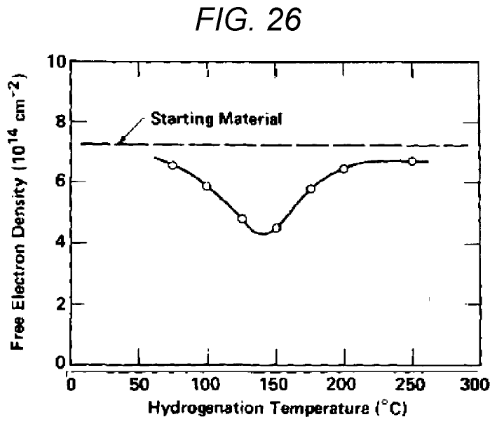

FIG. 26 is a graph illustrating a relationship between a hydrogenation temperature and a concentration of a mobile electron.

As illustrated in FIG. 26, it can be seen that the concentration of the mobile electron is lowered by the hydrogenation treatment. Particularly, when the hydrogenation treatment is performed at a temperature of about 150° C., the concentration of the mobile electron is maximally lowered. That is, the impurity in the semiconductor body 210 can be maximally inactivated when the hydrogenation treatment is performed at a temperature of about 150° C.

Furthermore, the hydrogenation treatment causes hydrogen to be introduced into the semiconductor body 210 and, as such, the hydrogen concentration in the semiconductor body 210 becomes high. For example, the hydrogen concentration of the semiconductor body 210 is higher than the hydrogen concentration of the semiconductor source layer BSL and the silicon cap layer CAP illustrated in FIGS. 20 and 21, which are formed after the semiconductor body 210 is formed.

The embodiments are merely examples, and the scope of the present disclosure is not limited thereto.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device, comprising:
a stacked body formed by alternately stacking, in a first direction, a plurality of first insulating layers and a plurality of first conductive layers, each of which functions as a control gate of a memory cell transistor;
a first columnar body extending in the first direction in the stacked body, the first columnar body comprising a first semiconductor portion;
an insulating film disposed at an end portion of the semiconductor memory device; and
a second columnar body extending in the first direction in the insulating film, the second columnar body comprising a second semiconductor portion shorter than the first semiconductor portion in the first direction, wherein
an impurity concentration of the second semiconductor portion at a bottom portion of the second columnar body is higher than an impurity concentration of the first semiconductor portion at an intersection portion between the first columnar body and the first conductive layer.

2. The semiconductor memory device according to claim 1, wherein
the first and second semiconductor portions include a polysilicon film, and
a particle diameter of a crystal of the polysilicon film is 80 nm or more.

3. The semiconductor memory device according to claim 1, wherein the impurity concentration of the second semiconductor portion at the bottom portion of the second columnar body is higher than impurity the concentration of the second semiconductor portion at a first portion different from the bottom portion of the second columnar body.

4. The semiconductor memory device according to claim 3, wherein the impurity concentration at the first portion of the second columnar body is equal to the impurity concentration of the first semiconductor portion at the intersection portion of the first columnar body.

5. The semiconductor memory device according to claim 1, wherein the impurity concentration of the second semiconductor portion at the bottom portion of the second columnar body is 1×10²⁰ cm⁻³ or higher.

6. The semiconductor memory device according to claim 5, wherein the impurity concentration of the first semiconductor portion at the intersection portion between the first columnar body and the first conductive layer is 5×10¹⁹ cm⁻³ or lower.

7. A semiconductor memory device comprising:
a stacked body formed by alternately stacking a plurality of first insulating layers and a plurality of first conductive layers in a first direction; and
a columnar body comprising a first semiconductor portion and a second insulator portion disposed between the first semiconductor portion and the stacked body, wherein
an intersection portion between the plurality of first conductive layers and the first semiconductor portion functions as a transistor, and
first conductive type impurity concentration of the first semiconductor portion is 1×10²⁰ cm⁻³ or higher at the intersection portion.

8. The semiconductor memory device according to claim 7, wherein a carrier concentration of the first semiconductor portion is lower than the impurity concentration.

9. The semiconductor memory device according to claim 7, wherein
the first semiconductor portion includes an n-type impurity, and
a concentration of a mobile electron of the first semiconductor portion is lower than a concentration of the n-type impurity.

10. A semiconductor memory device comprising:
a stacked body formed by alternately stacking, in a first direction, a plurality of first insulating layers and a plurality of first conductive layers each of the plurality of first insulating layers and the plurality of first conductive layers functions as a control gate of a memory cell transistor;
a source line disposed on one side of the stacked body in the first direction, the source line comprising a semiconductor layer; and
a first columnar body extending in the first direction in the stacked body, an end of the first columnar body reaching an inside of the semiconductor layer, the first columnar body comprising a first semiconductor portion, wherein
a first conductive type impurity concentration of the first semiconductor portion is 1×10²⁰ cm⁻³ or higher in at least a part of an area located in the semiconductor layer.

11. A manufacturing method of a semiconductor memory device, comprising:
forming a stacked body by alternately stacking a first insulating layer and a first sacrifice film in a first direction;
forming a hole extending in the first direction in the stacked body;
performing, on an inner wall of the hole, film formation of a second insulator portion;
performing film formation of a first semiconductor portion on an inner side of the second insulator portion in the hole, wherein the first semiconductor portion is doped with a first conductive type impurity;
crystallizing the first semiconductor portion doped with the impurity by performing a first heat treatment;
diffusing the impurity from the crystalized first semiconductor portion by performing a second heat treatment; and
removing the first sacrifice film so as to form a first conductive layer in a space formed after the removal of the first sacrifice film.

12. The manufacturing method according to claim 11, further comprising:
performing film formation of a material film on an inner side of the first semiconductor portion in the hole, in which the material film is not doped with the impurity;
diffusing, into the material film, the impurity of the first semiconductor portion by performing the second heat treatment; and
removing the material film having the impurity diffused thereinto.

13. The manufacturing method according to claim 12, further comprising burying the first insulator portion after the film formation of the material film and the removal of the material film are repeatedly performed a plurality of times.

14. The manufacturing method according to claim 12, wherein an impurity concentration of the first semiconductor portion after the removal of the material film is 5×10¹⁹ cm⁻³ or lower.

15. The manufacturing method according to claim 12, wherein a particle diameter of a crystal of the first semiconductor portion after the heat treatment is 80 nm or more.

16. A manufacturing method of a semiconductor memory device, comprising:
forming a stacked body by alternately stacking a first insulating layer and a first sacrifice film in a first direction;
forming a hole extending in the first direction in the stacked body;
performing, on an inner wall of the hole, film formation of a second insulator portion;
performing film formation of a first semiconductor portion on an inner side of the second insulator portion in the hole, in which the first semiconductor portion is doped with a first conductive type impurity;
crystallizing the first semiconductor portion doped with the impurity by performing a first heat treatment;
diffusing hydrogen into the crystalized first semiconductor portion by performing a second heat treatment; and
removing the first sacrifice film so as to form a first conductive layer in a space formed after the removal of the first sacrifice film.

17. The manufacturing method according to claim 16, further comprising:
performing film formation of a material film on an inner side of the first semiconductor portion in the hole, in which the material film is not doped with the impurity;
diffusing, into the material film, the impurity of the first semiconductor portion by performing the second heat treatment; and
removing the material film having the impurity diffused thereinto.

18. The manufacturing method according to claim 17, further comprising burying a first insulator portion after the film formation of the material film and the removal of the material film are repeatedly performed a plurality of times.

19. The manufacturing method according to claim 17, wherein an impurity concentration of the first semiconductor portion after the removal of the material film is 5×10¹⁹ cm⁻³ or lower.

20. The manufacturing method according to claim 17, wherein a particle diameter of a crystal of the first semiconductor portion after the heat treatment is 80 nm or more.
